(19) United States
(12) Patent Application Publication
(10) Pub. No.: US 2019/0064226 A1
(43) Pub. Date: Feb. 28, 2019

(54) DETECTING DEVICE

(71) Applicant: FANUC CORPORATION, Yamanashi (JP)

(72) Inventors: Yuuki FUKUMOTO, Yamanashi-ken (JP); Shougo TAKAHASHI, Yamanashi-ken (JP)

(21) Appl. No.: 16/108,571

(22) Filed: Aug. 22, 2018

(30) Foreign Application Priority Data
Aug. 28, 2017 (JP) 2017-163592

(51) Int. Cl. G01R 17/10; G05D 23/24; G01B 7/16

(52) U.S. Cl. CPC G01R 17/105; G01B 7/18; G05D 23/24

(57) ABSTRACT

A detecting device includes: a bridge circuit having at least one sensing resistor whose resistance varies according to a physical quantity of a measurement object; a constant voltage power supply configured to apply a constant voltage to the bridge circuit; a first amplifier having high-impedance input terminals and configured to receive an input voltage of the bridge circuit from the input terminals, amplify the received input voltage and output the amplified input voltage; and an input voltage monitoring unit configured to receive the input voltage amplified by the first amplifier and monitor the voltage of the input voltage. The bridge circuit is connected to the first amplifier via a connector.

### CROSS-REFERENCE TO RELATED APPLICATION

This application is based upon and claims the benefit of priority from Japanese Patent Application No. 2017-163592 filed on Aug. 28, 2017, the contents of which are incorporated herein by reference.

### BACKGROUND OF THE INVENTION

### Field of the Invention

The present invention relates to a detecting device including a bridge circuit of a plurality of resistors including at least one sensing resistor whose resistance varies according to a physical quantity of an object to be measured.

### Description of the Related Art

Japanese Laid-Open Patent Publication No. 2004-093321 discloses a bridge circuit type detecting device that uses a bridge voltage detection circuit to detect a variation of the input voltage of a bridge circuit to which a constant current is supplied from a constant current circuit and automatically compensates a measurement error arising due to temperature drift, in accordance with the variation of the input voltage of the bridge circuit.

### SUMMARY OF THE INVENTION

In the technique described in Japanese Laid-Open Patent Publication No. 2004-093321, a voltage drop occurs between the bridge circuit and the bridge voltage detection circuit, so that there is a possibility that the bridge voltage detection circuit cannot accurately detect the input voltage of the bridge voltage.

The present invention has been devised to solve the above problem, and it is therefore an object of the present invention to provide a detecting device capable of accurately detecting the input voltage of a bridge circuit.

According to an aspect of the present invention, a detecting device includes: a bridge circuit having a plurality of resistors including at least one sensing resistor whose resistance varies according to a physical quantity of a measurement object; a constant voltage power supply configured to apply a constant voltage to the bridge circuit; a first amplifier having high-impedance input terminals and configured to receive an input voltage of the bridge circuit from the input terminals, amplify the received input voltage and output the amplified input voltage; and an input voltage monitoring unit configured to receive the input voltage amplified by the first amplifier and monitor the voltage of the input voltage, wherein the bridge circuit is connected to the first amplifier via a connector.

According to the present invention, it is possible to accurately detect the input voltage of the bridge circuit.

The above and other objects, features, and advantages of the present invention will become more apparent from the following description when taken in conjunction with the accompanying drawings in which a preferred embodiment of the present invention is shown by way of illustrative example.

### BRIEF DESCRIPTION OF THE DRAWINGS

FIG. 1 is a diagram showing a circuit configuration of a detecting device according to an embodiment of the present invention;

FIG. 2 is a schematic diagram showing a state in which a detecting device is multilayered;

FIG. 3 is a diagram showing a circuit configuration of a detecting device of a comparative example;

FIG. 4 is a diagram showing a circuit configuration of a detecting device according to another embodiment of the present invention;

FIG. 5 is a diagram showing a circuit configuration of a detecting device according to a modification;

FIG. 6 is a diagram showing a circuit configuration of a detecting device according to another modification;

FIG. 7 is a diagram showing a circuit configuration of a detecting device according to another modification; and

FIG. 8 is a diagram showing a circuit configuration of a detecting device according to another modification.

### DESCRIPTION OF THE PREFERRED EMBODIMENTS

### First Embodiment

### [Configuration of Detecting Device]

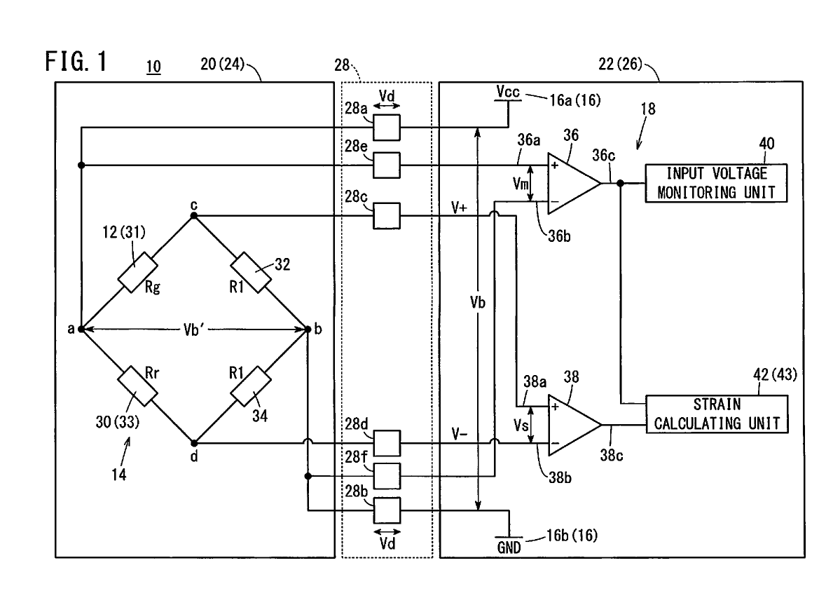

FIG. 1 is a diagram showing a circuit configuration of a detecting device 10. The detecting device 10 of the present embodiment detects change in resistance of a strain gauge 12 stuck or applied to an object to be measured (measurement object) such as a strain generating body of a load cell, and calculates an amount of strain arising in the measurement object from the change in resistance. Based on the strain amount of the measurement object, a physical quantity to be measured, such as load, pressure, torque, tensile force, shear force, etc., acting on the measurement object can be obtained. Here, instead of the strain gauge 12, a detecting element whose resistance changes depending on gas concentration may be used to detect gas concentration as a physical quantity to be measured.

The detecting device 10 includes a bridge circuit 14, a constant voltage power supply 16 and a detection circuit 18. The bridge circuit 14 is provided on a flexible printed circuit board (hereinafter referred to as FPC) 20, and the constant voltage power supply 16 and the detection circuit 18 are provided on a printed circuit board (hereinafter referred to as PCB) 22. The FPC 20 constitutes a first substrate 24, and the PCB 22 constitutes a second substrate 26. The FPC 20 and the PCB 22 are connected by a connector 28.

The bridge circuit 14 includes a strain gauge 12, a temperature compensation gauge 30, a resistor 32 and a resistor 34. The strain gauge 12 constitutes a sensing resistor 31, and the temperature compensation gauge 30 constitutes a reference resistor 33. The strain gauge 12 is stuck or applied to a place where deformation or strain occurs when a load acts on the object to be measured. The temperature compensation gauge 30 is affixed to a place where no deformation occurs even if a load acts on the measurement object.

In the measurement object, deformation occurs due to a load acting on the measurement object, and also occurs depending on the ambient temperature. As the strain gauge 12 and the temperature compensation gauge 30 are attached to the aforementioned respective places, the strain gauge 12 changes its resistance depending on the load which is the measurement target physical quantity of the measurement object and also depending on the ambient temperature which is a physical quantity other than the measurement target, while the temperature compensation gauge 30 changes its resistance only in accordance with the ambient temperature which is the physical quantity other than the measurement target. The resistor 32 and the resistor 34 are fixed resistors.

The strain gauge 12 and the temperature compensation gauge 30 change their resistance depending on the amounts of strain of the measurement object. The bridge circuit 14 is adjusted so as to maintain a balanced state (output voltage=0) when strain is generated in the measurement object due to a change in ambient temperature with no load being applied to the measurement object. On the other hand, when strain occurs due to a load acting on the measurement object, the bridge circuit 14 loses balance (i.e., no longer maintains the balanced state) and generates an output voltage. It is possible to calculate the load acting on the measurement object from the magnitude of the output voltage.

The strain gauge 12 and the temperature compensation gauge 30 are connected at a contact point a, the resistor 32 and the resistor 34 are connected at a contact point b, the strain gauge 12 and the resistor 32 are connected at a contact point c, and the temperature compensation gauge 30 and the resistor 34 are connected at a contact point d. The strain gauge 12, the temperature compensation gauge 30, the resistor 32 and the resistor 34 are arranged at intervals that are equal to or less than a predetermined distance. As a result, the ambient temperatures of the strain gauge 12, the temperature compensation gauge 30, the resistor 32 and the resistor 34 are set to be substantially the same.

The constant voltage power supply 16 is a DC (direct current) power source, and supplies a constant voltage of 2 V (=Vb) to the bridge circuit 14. The detection circuit 18 includes a first amplifier 36, a second amplifier 38, an input voltage monitoring unit 40 and a strain calculating unit 42. The first amplifier 36 is an instrumentation amplifier having two high-impedance differential input terminals (input terminals 36a and 36b) and a low-impedance output terminal 36c. The second amplifier 38 is an instrumentation amplifier having two high-impedance differential input terminals (input terminals 38a, 38b) and a low-impedance output terminal 38c. The first amplifier 36 amplifies the potential difference between the contact point a and the contact point b input from the input terminals 36a and 36b, and outputs the resultant to the output terminal 36c. The second amplifier 38 amplifies the potential difference between the contact point c and the contact point d, which is input to the input terminals 38a and 38b, and outputs the resultant to the output terminal 38c.

The input voltage monitoring unit 40 receives the potential difference amplified by the first amplifier 36 and monitors the input voltage (the potential difference between the contact point a and the contact point b) of the bridge circuit 14. The strain calculating unit 42 receives the potential difference amplified by the first amplifier 36 and the potential difference amplified by the second amplifier 38 and calculates the strain acting on the measurement object. The strain calculating unit 42 constitutes a physical quantity calculating unit 43.

The strain gauge 12 and the temperature compensation gauge 30 are connected at the contact point a to a positive electrode 16a of the constant voltage power supply 16. The contact point a and the positive electrode 16a are connected by a connector 28a. Wiring between the positive electrode 16a and the strain gauge 12 and wiring between the positive electrode 16a and the temperature compensation gauge 30 are formed so that the resistance between the positive electrode 16a and the strain gauge 12 and the resistance between the positive electrode 16a and the temperature compensation gauge 30 are equal to each other. Further, wiring between the positive electrode 16a and the bridge circuit 14 is formed by a solid pattern of a predetermined width or greater. Thereby, the resistance of the wiring between the positive electrode 16a and the bridge circuit 14 can be minimized.

The resistor 32 and the resistor 34 are connected at the contact point b to a negative electrode 16b of the constant voltage power supply 16. The contact point b and the negative electrode 16b are connected by a connector 28b. Wiring between the negative electrode 16b and the resistor 32 and wiring between the negative electrode 16b and the resistor 34 are formed so that the resistance between the negative electrode 16b and the resistor 32 and the resistance between the negative electrode 16b and the resistor 34 are equal to each other. Further, wiring between the negative electrode 16b and the bridge circuit 14 is formed by a solid pattern of a predetermined width or greater. Thereby, the resistance of the wiring between the negative electrode 16b and the bridge circuit 14 can be minimized.

The strain gauge 12 and the resistor 32 are connected at the contact point c to the positive input terminal 38a of the second amplifier 38. The contact point c and the input terminal 38a are connected via a connector 28c. The temperature compensation gauge 30 and the resistor 34 are connected at the contact point d to the negative input terminal 38b of the second amplifier 38. The contact point d and the input terminal 38b are connected via a connector 28d. As a result, the output voltage from the bridge circuit 14 is input to the second amplifier 38.

The strain gauge 12 and the temperature compensation gauge 30 are connected at the contact point a to the positive input terminal 36a of the first amplifier 36. The contact point a and the input terminal 36a are connected via a connector 28e. The resistor 32 and the resistor 34 are connected at the contact point b to the negative input terminal 36b of the first amplifier 36. The contact point b and the input terminal 36b are connected via a connector 28f. As a result, the input voltage to the bridge circuit 14 is input to the first amplifier 36.

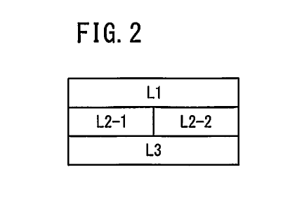

FIG. 2 is a schematic diagram showing a multilayered state of the detecting device 10. The bridge circuit 14 is disposed in a layer L2-1 while the constant voltage power supply 16 and the detection circuit 18 are disposed in the layer L2-2. The wiring between the positive electrode 16a and the bridge circuit 14 is disposed in the layer L1, and the wiring between the negative electrode 16b and the bridge circuit 14 is disposed in the layer L3. That is, the layer L1 including therein the wiring between the positive electrode 16a of a solid pattern and the bridge circuit 14, and the layer L3 including therein the wiring between the negative electrode 16b of a solid pattern and the bridge circuit 14 are arranged to sandwich therebetween the layer L2-1 having the bridge circuit 14 therein and the layer L2-2 having therein the constant voltage power supply 16 and the detection circuit 18. As a result, it is possible to suppress noise contamination of the signals of the bridge circuit 14, the constant voltage power supply 16 and the detection circuit 18 caused by external electromagnetic waves or the like.

### [Calculation of Strain Amount]

A method of calculating a strain amount of the measurement object in the strain calculating unit 42 will be described. A potential difference between the positive electrode 16a and the negative electrode 16b of the constant voltage power supply 16 is denoted by Vb. At this time, Vb′, which denotes the potential difference between the contact points a and b, is smaller than Vb (Vb′<Vb). This is because a voltage drop occurs due to the resistance of the connector 28a and the connector 28b.

As shown in FIG. 1, Rg denotes the resistance of the strain gauge 12, Rr denotes the resistance of the temperature compensation gauge 30, and R1 denotes the resistance of the resistor 32 and the resistor 34. Further, the connector 28a and the connector 28b each have a voltage drop of Vd. Since the input terminals 36a and 36b of the first amplifier 36 and the input terminals 38a and 38b of the second amplifier 38 have high impedance so that almost no current flows, the voltage drops at the connectors 28c to 28f can be neglected.

Assuming that the voltage input to the positive input terminal 38a of the second amplifier 38 is V+, the voltage V+ can be determined by the following equation:

V+=Vb′×[R1/(Rg+R1)]+Vd.

Assuming that the voltage input to the negative input terminal 38b of the second amplifier 38 is V−, the voltage V− can be determined by the following equation:

V−=Vb′×[R1/(Rr+R1)]+Vd.

From the above two equations, the potential difference Vs input to the second amplifier 38 is obtained by the following equation:

$$\begin{matrix}Vs = ( V + ) - ( V - ) \\ = {Vb}^{′} \times \{ [ R 1 / ( Rg + R 1 ) ] - [ R 1 / ( Rr + R 1 ) ] \} .\end{matrix}$$

Herein, Vm, which denotes the potential difference input to the first amplifier 36, has the following relationship:

Vm=Vb′.

Therefore,

Vs/Vm=[R1/(Rg+R1)]−[R1/(Rr+R1)].

Thus, a value that is not affected by the value of Vb′ is obtained.

The strain calculating unit 42 has a preset map indicating the relationship between the amount of strain acting on the measurement object and the value of Vs/Vm, and calculates the strain amount according to Vs/Vm. Since the resistance of the strain gauge 12 and the resistance of the temperature compensation gauge 30 are equal to each other for a strain of the measurement object caused by change in ambient temperature, Vs/Vm=0 holds when no load acts on the measurement object.

### [Input Voltage Monitoring]

The input voltage monitoring unit 40 monitors or checks the potential difference Vb′ between the contact point a and the contact point b. The input voltage monitoring unit 40 also operates in cooperation with the strain calculating unit 42. For example, in a case that the value of Vs/Vm calculated by the strain calculating unit 42 falls outside a predetermined range, the input voltage monitoring unit 40 determines that an abnormality has occurred in the constant voltage power supply 16 when the potential difference Vb′ falls outside a predetermined range, whereas the input voltage monitoring unit 40 determines that an abnormality has occurred in the bridge circuit 14 when the potential difference Vb′ falls within the predetermined range.

### [Operation and Effect]

### Configuration of Comparative Example

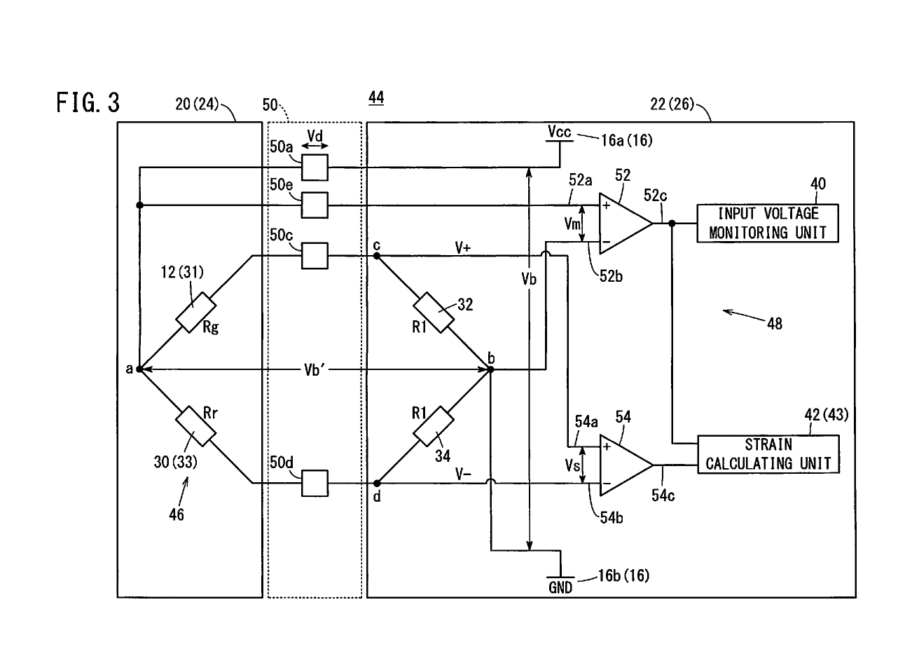

FIG. 3 is a diagram showing a circuit configuration of a detecting device 44 of a comparative example. Hereinafter, the circuit configuration of the detecting device 44 will be described, but description of the same components as those of the detecting device 10 of the present embodiment will be omitted.

The detecting device 44 has a bridge circuit 46, a constant voltage power supply 16 and a detection circuit 48. Of the bridge circuit 46, the strain gauge 12 and the temperature compensation gauge 30 are provided on the FPC 20, and the resistor 32 and the resistor 34 are provided on the PCB 22. The constant voltage power supply 16 and the detection circuit 48 are provided on the PCB 22. The FPC 20 and the PCB 22 are connected by a connector 50.

In the detecting device 44 of the comparative example, the strain gauge 12 and the temperature compensation gauge 30 are connected at a contact point a, the resistor 32 and the resistor 34 are connected at a contact point b, the strain gauge 12 and the resistor 32 are connected at a contact point c, and the temperature compensation gauge 30 and the resistor 34 are connected at a contact point d.

The strain gauge 12 and the temperature compensation gauge 30 are connected at the contact point a to the positive electrode 16a of the constant voltage power supply 16. The contact point a and the positive electrode 16a are connected via a connector 50a. The resistor 32 and the resistor 34 are connected at the contact point b to the negative electrode 16b of the constant voltage power supply 16. The contact point b and the negative electrode 16b are connected by wiring on the PCB 22.

The strain gauge 12 and the resistor 32 are connected at the contact point c to a positive input terminal 54a of a fourth amplifier 54. The strain gauge 12 and the contact point c are connected by a connector 50c. The temperature compensation gauge 30 and the resistor 34 are connected at the contact point d to a negative input terminal 54b of the fourth amplifier 54. The temperature compensation gauge 30 and the contact point d are connected by a connector 50d.

The strain gauge 12 and the temperature compensation gauge 30 are connected at the contact point a to a positive input terminal, designated at 52a, of a third amplifier 52. The contact point a and the input terminal 52a are connected via a connector 50e. The resistor 32 and the resistor 34 are connected at the contact point b to a negative input terminal, designated at 52b, of the third amplifier 52. The contact point b and the input terminal 52b are connected by wiring on the PCB 22.

The detection circuit 48 includes the third amplifier 52, the fourth amplifier 54, the input voltage monitoring unit 40, and the strain calculating unit 42. The third amplifier 52 is an instrumentation amplifier having two differential input terminals (input terminals 52a, 52b) which are not high impedance, and an output terminal 52c. The fourth amplifier 54 is an instrumentation amplifier having two differential input terminals (input terminals 54a, 54b) which are not high impedance, and an output terminal 54c. The third amplifier 52 amplifies the potential difference between the contact point a and the contact point b input from the input terminals 52a and 52b, and outputs the resultant to the output terminal 52c. The fourth amplifier 54 amplifies the potential difference between the contact point c and the contact point d, which is input to the input terminals 54a and 54b, and outputs the resultant to the output terminal 54c.

### Problems in Comparative Example

In the detecting device 44 of the comparative example, the connector 50e is provided between the contact point a and the input terminal 52a. Since the connector 50e has a resistance, a voltage drop occurs at the connector 50e, and the potential difference Vm input to the third amplifier 52 is lower than the potential difference Vb′ between the contact point a and the contact point b. Therefore, the input voltage monitoring unit 40 cannot accurately detect the input voltage (=Vb′) input to the bridge circuit 46.

Since the bridge circuit 46 includes the connector 50c and the connector 50d, the resistances of the connector 50c and the connector 50d affect the potential difference between the contact point c and the contact point d, so that it is impossible for the strain calculating unit 42 to accurately detect the output voltage.

### Operation and Effect of the Embodiment

To deal with the above, in the present embodiment, as shown in the circuit diagram of the detecting device 10 in FIG. 1, the connector 28 is arranged outside the bridge circuit 14. Further, the bridge circuit 14 and the first amplifier 36 having the high-impedance input terminals 36a and 36b are connected by the connectors 28e and 28f. Further, the input voltage to the bridge circuit 14 is amplified by the first amplifier 36 and is supplied to the input voltage monitoring unit 40, so that the input voltage monitoring unit monitors or checks the input voltage. Thereby, almost no current flows between the bridge circuit 14 and the first amplifier 36, and hence the voltage drops at the connectors 28e and 28f can be reduced to a negligible level. As a result, the input voltage monitoring unit 40 can accurately detect the input voltage input to the bridge circuit 14.

Further, in the present embodiment, the bridge circuit 14 is provided on the FPC 20 and the first amplifier 36 is provided on the PCB 22, and the FPC 20 and the PCB 22 are connected by the connector 28. Thereby, since the bridge circuit 14 can be formed by the wiring on the FPC 20, it is possible to minimize the resistances between the associated pairs of resistors 12, 30, 32 and 34. As a result, it is possible for the input voltage monitoring unit 40 to accurately detect the input voltage input to the bridge circuit 14. Furthermore, the substrate (FPC 20) on which the bridge circuit 14 having the strain gauge 12 to be attached to the measurement object is provided and the substrate (PCB 22) on which the first amplifier 36 constituting the detection circuit 18 is provided can be separated from each other. As a result, even if the detecting device 10 breaks down or is out of order, the device can be fixed merely by replacing one of the FPC 20 and the PCB 22, so that the cost is suppressed, as compared with the case where the entire detecting device 10 is replaced.

Further, in the present embodiment, the bridge circuit 14 and the second amplifier 38 having the high-impedance input terminals 38a and 38b are connected by the connectors 28c and 28d. The input voltage to the bridge circuit 14 is amplified by the first amplifier 36 while the output voltage from the bridge circuit 14 is amplified by the second amplifier 38, and the amplified input voltage and the amplified output voltage are input to the strain calculating unit 42. Thus, the strain calculating unit 42 calculates the strain of the measurement object based on the input voltage to the bridge circuit and the output voltage from the bridge circuit. Thereby, almost no current flows between the bridge circuit 14 and the second amplifier 38, and hence the voltage drops at the connectors 28c and 28d can be reduced to a negligible level. As a result, the strain calculating unit 42 can accurately detect the output voltage output from the bridge circuit 14. Further, in the strain calculating unit 42, by dividing the output voltage of the bridge circuit 14 by the input voltage thereof, a value not affected by the input voltage can be obtained. Therefore, it is possible to accurately detect the amount of strain acting on the measurement object.

Further, in the present embodiment, the bridge circuit 14 is provided on the FPC 20, whereas the second amplifier 38 is provided on the PCB 22, and the FPC 20 and the PCB 22 are connected by the connector 28. Thereby, since the bridge circuit 14 can be formed by the wiring on the FPC 20, it is possible to minimize the resistances between the associated pairs of resistors 12, 30, 32 and 34. As a result, it is possible for the strain calculating unit 42 to accurately detect the output voltage from the bridge circuit 14. Furthermore, the substrate (FPC 20) on which the bridge circuit 14 having the strain gauge 12 to be attached to the measurement object is provided and the substrate (PCB 22) on which the second amplifier 38 constituting the detection circuit 18 is provided are configured separately. As a result, even if the detecting device 10 breaks down, the device can be fixed merely by replacing one of the FPC 20 and the PCB 22, so that the cost is suppressed, as compared with the case where the entire detecting device 10 is replaced.

Further, in the present embodiment, the strain gauge 12, the temperature compensation gauge 30, the resistor 32 and the resistor 34 of the bridge circuit 14 are arranged at intervals that are each equal to or less than a predetermined distance. As a result, the strain gauge 12, the temperature compensation gauge 30, the resistor 32 and the resistor 34 can be kept at substantially the same ambient temperature. Therefore, it is possible to suppress detection errors of the input and output voltages of the bridge circuit 14 due to change in resistance depending on the ambient temperature.

Further, in the present embodiment, the wiring between the positive electrode 16a of the constant voltage power supply 16 and the strain gauge 12 and the wiring between the positive electrode 16a and the temperature compensation gauge 30 are provided so that the resistance between the positive electrode 16a and the strain gauge 12 is equal to the resistance between the positive electrode 16a and the temperature compensation gauge 30. Furthermore, in the present embodiment, the wiring between the negative electrode 16b of the constant voltage power supply 16 and the resistor 32 and the wiring between the negative electrode 16b and the resistor 34 are provided so that the resistance between the negative electrode 16b and the resistor 32 is equal to the resistance between the negative electrode 16b and the resistor 34. Thus, it is possible to suppress detection errors of the input voltage and the output voltage of the bridge circuit 14 due to difference in resistance of wiring.

Further, in the present embodiment, the wiring between the positive electrode 16a of the constant voltage power supply 16 and the bridge circuit 14 and the wiring between the negative electrode 16b and the bridge circuit 14 are formed with a solid pattern having a predetermined width or greater. This makes it possible to minimize the resistance of the wiring between the positive electrode 16a and the bridge circuit 14 and the resistance of the wiring between the negative electrode 16b and the bridge circuit 14. Therefore, detection errors of the input voltage and the output voltage of the bridge circuit 14 caused by the resistance of wiring can be suppressed.

In the present embodiment, the layer L1 in which the wiring between the positive electrode 16a of the constant voltage power supply 16 and the bridge circuit 14 is disposed and the layer L3 in which the wiring between the negative electrode 16b and the bridge circuit 14 is disposed are arranged so as to sandwich the layer L2-1 having therein the bridge circuit 14. As a result, it is possible to prevent the input voltage and the output voltage of the bridge circuit 14 from being contaminated with noise due to external electromagnetic waves or the like.

### Second Embodiment

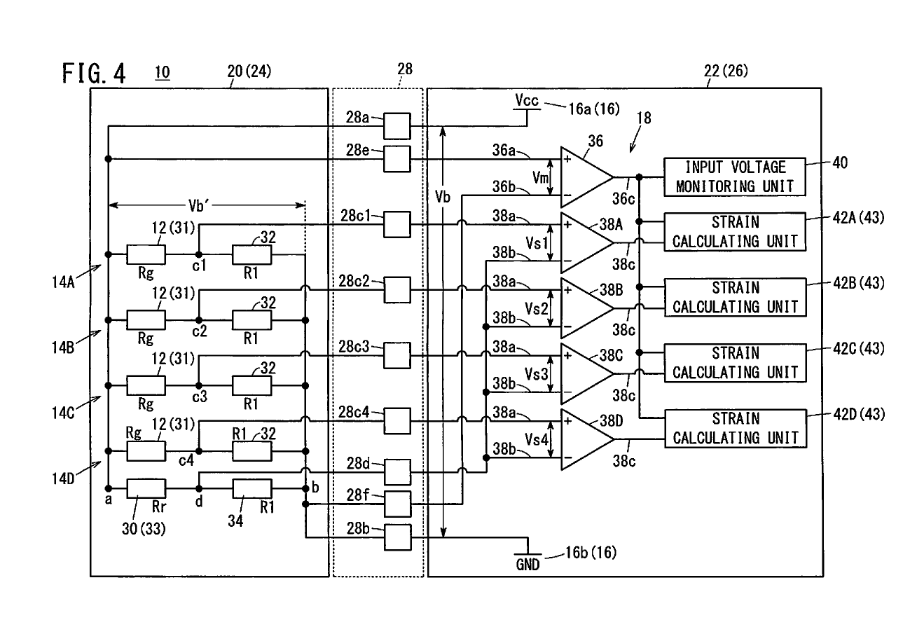

FIG. 4 is a diagram showing a circuit configuration of a detecting device 10 of a second embodiment. In the second embodiment, four bridge circuits 14A to 14D are provided on an FPC 20. Each of the bridge circuits 14A to 14D has a strain gauge 12 and a resistor 32, while a temperature compensation gauge 30 and a resistor 34 are shared by the bridge circuits 14A to 14D. Also, a constant voltage power supply 16 and an input voltage monitoring unit 40 are not provided for each of the bridge circuits 14A to 14D, but are shared by the bridge circuits 14A to 14D. Hereinafter, the circuit configuration of the detecting device 10 of the present embodiment will be described, but description of the same components as those of the detecting device 10 of the first embodiment will be omitted.

In the detecting device 10 of the present embodiment, the strain gauge 12 in each of the bridge circuits 14A to 14D and the shared temperature compensation gauge 30 are connected at the contact point a, and the resistor 32 in each of the bridge circuits 14A to 14D and the shared resistor 34 are connected at the contact point b. In each of the bridge circuits 14A to 14D, the strain gauge 12 and the resistor 32 are connected at the associated contact point c1 to c4. The shared temperature compensation gauge 30 and the shared resistor 34 are connected at the contact point d.

The constant voltage power supply 16 is a DC power supply and supplies a constant voltage of 2 V (=Vb) to each of the bridge circuits 14A to 14D. The detection circuit 18 includes a first amplifier 36, second amplifiers 38A to 38D, an input voltage monitoring unit 40, and strain calculating units 42A to 42D. The first amplifier 36 is an instrumentation amplifier having two high-impedance differential input terminals (input terminals 36a and 36b), and a low-impedance output terminal 36c. The second amplifiers 38A to 38D each are an instrumentation amplifier having two high-impedance differential input terminals (input terminals 38a and 38b), and a low-impedance output terminal 38c. The first amplifier 36 amplifies the potential difference between the contact point a and the contact point b input from the input terminals 36a and 36b and outputs the resultant to the output terminal 36c. The second amplifiers 38A to 38D each amplify the potential difference between the contact point c and the contact point d, which is input to the input terminals 38a and 38b, and output the resultant to the output terminal 38c.

The input voltage monitoring unit 40 receives the potential difference amplified by the first amplifier 36 and monitors the input voltage (the potential difference between the contact point a and the contact point b) to the bridge circuits 14A to 14D. Each of the strain calculating units 42A to 42D receives the potential difference amplified by the first amplifier 36 and the potential difference amplified by the corresponding one of the second amplifiers 38A to 38D, and calculates the strain acting on the measurement object.

The strain gauge 12 in each of the bridge circuits 14A to 14D and the shared temperature compensation gauge 30 are connected at the contact point a to the positive electrode 16a of the constant voltage power supply 16. The contact point a and the positive electrode 16a are connected by a connector 28a. The resistor 32 in each of the bridge circuits 14A to 14D and the shared resistor 34 are connected to the negative electrode 16b of the constant voltage power supply 16 at the contact point b. The contact point b and the negative electrode 16b are connected by a connector 28b.

The strain gauge 12 in each of the bridge circuits 14A to 14D and the resistors 32 in each of the bridge circuits 14A to 14D are connected at the associated one of the contact points c1 to c4 to the positive input terminal 38a of the associated one of the second amplifiers 38A to 38D. The contact points c1 to c4 and the input terminals 38a are connected via the connectors 28c1 to 28c4, respectively. The shared temperature compensation gauge 30 and the shared resistor 34 are connected at the contact point d to the negative input terminals 38b of the second amplifiers 38A to 38D. The contact point d and the input terminals 38b are connected via a connector 28d. Thus, the output voltages from the bridge circuits 14A to 14D are input to the second amplifiers 38A to 38D, respectively.

The potential differences Vs1 to Vs4 input to the second amplifiers 38A to 38D can be obtained by the same method as that described in the first embodiment to obtain the potential difference Vs input to the second amplifier 38.

The strain gauges 12 of the bridge circuits 14A to 14D and the shared temperature compensation gauge 30 are connected at the contact point a to the positive input terminal 36a of the first amplifier 36. The contact point a and the input terminal 36a are connected via a connector 28e. The resistors 32 of the bridge circuits 14A to 14D and the shared resistor 34 are connected at the contact point b to the negative input terminal 36b of the first amplifier 36. The contact point b and the input terminal 36b are connected via a connector 28f. As a result, the input voltage to the bridge circuit 14 is input to the first amplifier 36.

### [Operation and Effect]

In this embodiment, the detecting device 10 has a plurality of (four) bridge circuits 14A to 14D, and the constant voltage power supply 16 is shared by the bridge circuits 14A to 14D. Thereby, it is possible to downsize the detecting device 10 and suppress the manufacturing cost.

Further, in the present embodiment, the input voltage monitoring unit 40 is shared by the bridge circuits 14A to 14D. Thereby, it is possible to downsize the detecting device 10 and suppress the manufacturing cost.

Further, in the present embodiment, the temperature compensation gauge 30 is shared by the bridge circuits 14A to 14D. Thereby, it is possible to downsize the detecting device 10 and suppress the manufacturing cost.

### Modifications

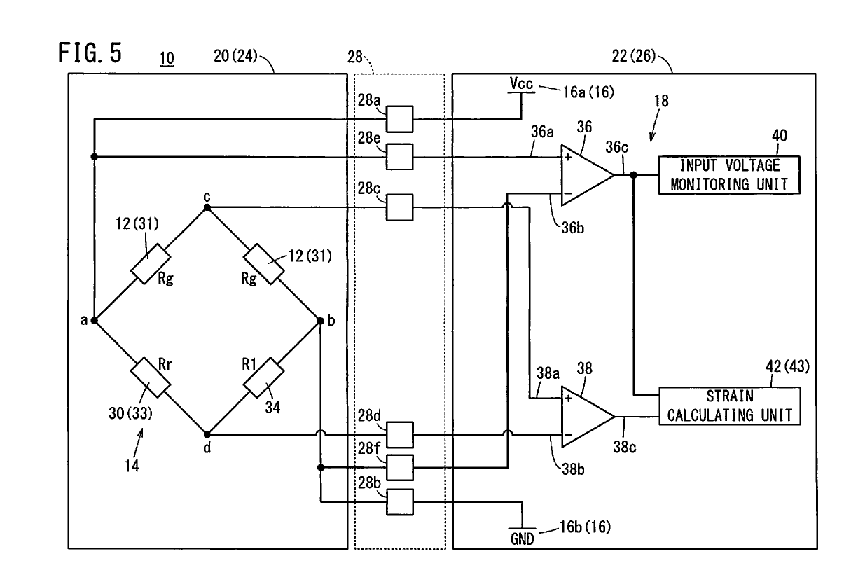

FIG. 5 is a diagram showing a circuit configuration of a detecting device 10 according to a modification. As shown in FIG. 5, another strain gauge 12 may be arranged at the position of the resistor 32 of the first embodiment (see FIG. 1), in place of the resistor 32. In this case, the bridge circuit 14 includes two strain gauges 12.

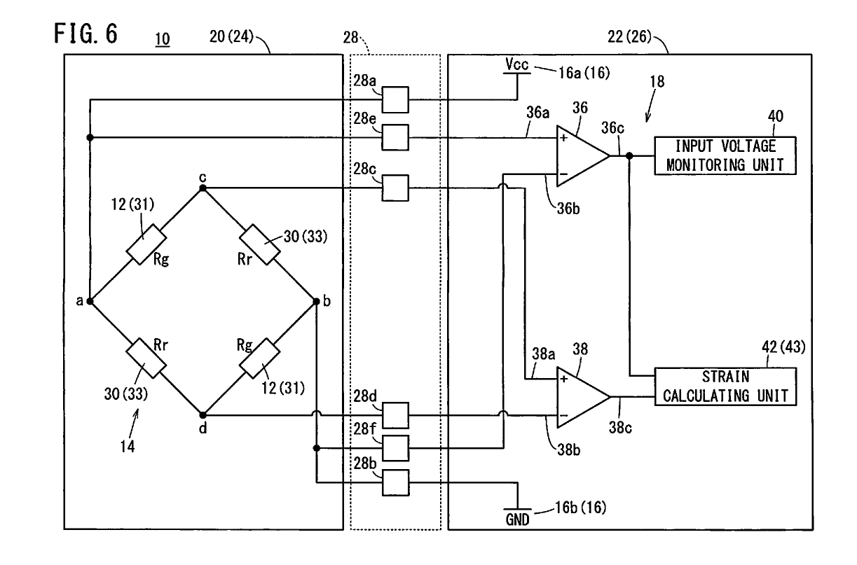

FIG. 6 is a diagram showing a circuit configuration of the detecting device 10 of another modification. As shown in FIG. 6, another strain gauge 12 may be disposed at the position of the resistor 34 of the first embodiment (see FIG. 1), in place of the resistor 34, and another temperature compensation gauge 30 may be disposed at the position of the resistor 32 of the first embodiment (see FIG. 1), in place of the resistor 32. In this case, the bridge circuit 14 includes two strain gauges 12 and two temperature compensation gauges 30.

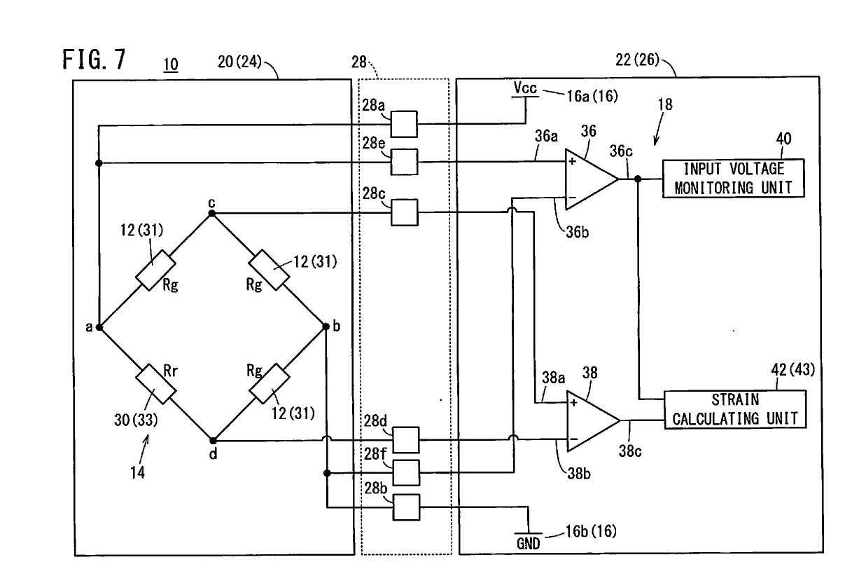

FIG. 7 is a diagram showing a circuit configuration of a detecting device 10 according to a further modification. As shown in FIG. 7, other strain gauges 12 may be arranged at the positions of the resistor 32 and the resistor 34 of the first embodiment (see FIG. 1), in place of the resistors 32, 34. In this case, the bridge circuit 14 includes three strain gauges 12.

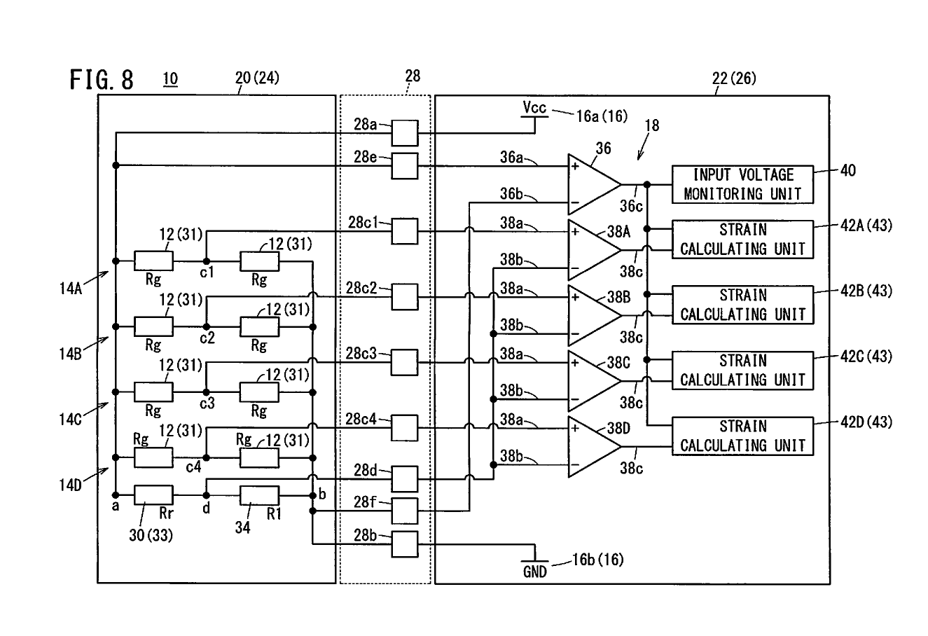

FIG. 8 is a diagram showing a circuit configuration of a detecting device 10 according to still another modification. As shown in FIG. 8, another strain gauge 12 may be arranged at the position of each of the resistors 32 of the second embodiment (see FIG. 4), in place of the resistors 32. In this case, each bridge circuit 14A to 14D includes two strain gauges 12.

### Technical Concepts Obtained from Embodiment

Technical concepts that can be grasped from the above embodiments will be described below.

The detecting device (10) includes: the bridge circuit (14, 14A to 14D) having a plurality of resistors (31 to 34) including at least one sensing resistor (31) whose resistance varies according to a physical quantity of a measurement object; the constant voltage power supply (16) configured to apply a constant voltage to the bridge circuit (14, 14A to 14D); the first amplifier (36) having high-impedance input terminals (36a, 36b) and configured to receive an input voltage of the bridge circuit (14, 14A to 14D) from the input terminals (36a, 36b), amplify the received input voltage and output the amplified input voltage; and the input voltage monitoring unit (40) configured to receive the input voltage amplified by the first amplifier (36) and monitor the voltage of the input voltage. The bridge circuit (14, 14A to 14D) is connected to the first amplifier (36) via the connector (28). Thereby, the input voltage monitoring unit (40) can accurately detect the input voltage applied to the bridge circuit (14, 14A to 14D).

In the above detecting device (10), the bridge circuit (14, 14A to 14D) may be provided on a first substrate (24), and the first amplifier (36) may be provided on a second substrate (26) provided separately from the first substrate (24). Thus, the input voltage monitoring unit (40) can accurately detect the input voltage applied to the bridge circuit (14, 14A to 14D). Further, if the detecting device (10) breaks down, the device (10) can be fixed merely by replacing one of the first substrate (24) and the second substrate (26), so that the cost can be reduced as compared with the case where the entire detecting device (10) is replaced.

The above detecting device (10) may further include: the second amplifier (38, 38A to 38D) having high-impedance input terminals (38a, 38b) and configured to receive an output voltage of the bridge circuit (14, 14A to 14D) from the input terminals (38a, 38b), amplify the received output voltage and output the amplified output voltage; and the physical quantity calculating unit (43) configured to receive the input voltage amplified by the first amplifier (36) and the output voltage amplified by the second amplifier (38, 38A to 38D), and calculate the physical quantity based on the input voltage and the output voltage. In this device, the bridge circuit (14, 14A to 14D) may be connected to the second amplifier (38, 38A to 38D) via the connector (28). As a result, since the voltage drop in the connector (28) can be reduced to a negligible level, the physical quantity calculating unit (43) can accurately detect the output voltage from the bridge circuit (14, 14A to 14D). Further, in the physical quantity calculating unit (43), by dividing the output voltage of the bridge circuit (14, 14A to 14D) by the input voltage thereof, it is possible to obtain a value not affected by the input voltage. Therefore, it is possible to accurately detect the amount of strain acting on the measuring object.

In the above detecting device (10), the bridge circuit (14, 14A to 14D) may be provided on the first substrate (24), while the first amplifier (36) and the second amplifier (38, 38A to 38D) may be provided on the second substrate (26) provided separately from the first substrate (24). Thus, the physical quantity calculating unit (43) can accurately detect the output voltage output from the bridge circuit (14, 14A to 14D). Further, even if the detecting device (10) breaks down, the device (10) can be fixed merely by replacing one of the first substrate (24) and the second substrate (26), so that the cost can be reduced as compared with the case where the entire detecting device (10) is replaced.

In the above detecting device (10), the plurality of resistors (31 to 34) in the bridge circuit (14, 14A to 14D) may be arranged at intervals that are equal to or less than a predetermined distance. This makes it possible to keep all the resistors (31 to 34) at substantially the same ambient temperature, so that it is possible to suppress detection errors of the input voltage and output voltage of the bridge circuit (14, 14A to 14D) due to change in resistance depending on the ambient temperature.

In the above detecting device (10), wiring between the constant voltage power supply (16) and the resistors (32, 34) may be arranged so that the resistance between the negative electrode (16b) of the constant voltage power supply (16) and each of the resistors (32, 34) connected to the negative electrode (16b) is equal to each other. This makes it possible to suppress detection errors of the input voltage and the output voltage of the bridge circuit (14, 14A to 14D) due to difference in resistance of wiring.

In the above detecting device (10), wiring between the constant voltage power supply (16) and the resistors (31, 33) may be arranged so that the resistance between the positive electrode (16a) of the constant voltage power supply (16) and each of the resistors (31, 33) connected to the positive electrode (16a) is equal to each other. This makes it possible to suppress detection errors of the input voltage and the output voltage of the bridge circuit (14, 14A to 14D) due to difference in resistance of wiring.

In the above detecting device (10), the wiring between the negative electrode (16b) of the constant voltage power supply (16) and the bridge circuit (14, 14A to 14D) may be formed of a solid pattern having a predetermined width or greater. Thereby, it is possible to suppress detection errors of the input voltage and the output voltage of the bridge circuit (14, 14A to 14D) caused by the resistance of wiring.

In the above detecting device (10), the wiring between the positive electrode (16a) of the constant voltage power supply (16) and the bridge circuit (14, 14A to 14D) may be formed of a solid pattern having a predetermined width or greater. Thereby, it is possible to suppress detection errors of the input voltage and the output voltage of the bridge circuit (14, 14A to 14D) caused by the resistance of wiring.

The above detecting device (10) may further include: the first layer (L1) provided with wiring between the positive electrode (16a) of the constant voltage power supply (16) and the bridge circuit (14, 14A to 14D); and the second layer (L2-1) provided with the bridge circuit (14, 14A to 14D), and the first layer (L1) and the second layer (L2-1) may be stacked together. This configuration restrains the input voltage and the output voltage of the bridge circuit (14, 14A to 14D) from being contaminated with noise due to external electromagnetic waves or the like.

The above detecting device (10) may further include: the second layer (L2-1) provided with the bridge circuit (14, 14A to 14D); and the third layer (L3) provided with wiring between the negative electrode (16b) of the constant voltage power supply (16) and the bridge circuit (14, 14A to 14D), and the second layer (L2-1) and the third layer (L3) may be stacked together. This configuration prevents the input voltage and the output voltage of the bridge circuit (14, 14A to 14D) from being contaminated with noise due to external electromagnetic waves or the like.

The above detecting device (10) may further include: the first layer (L1) provided with wiring between the positive electrode (16a) of the constant voltage power supply (16) and the bridge circuit (14, 14A to 14D); the second layer (L2-1) provided with the bridge circuit (14, 14A to 14D); and the third layer (L3) provided with wiring between the negative electrode (16b) of the constant voltage power supply (16) and the bridge circuit (14, 14A to 14D), and the second layer (L2-1) may be sandwiched between the first layer (L1) and the third layer (L3). This configuration suppresses noise contamination of the input voltage and the output voltage of the bridge circuit (14, 14A to 14D) caused by external electromagnetic waves or the like.

In the above detecting device (10), the plurality of the bridge circuits (14A to 14D) may be provided, and the constant voltage power supply (16) may be shared by the plural bridge circuits (14A to 14D). Thereby, it is possible to downsize the detecting device (10) and suppress the manufacturing cost.

In the above detecting device (10), the plurality of the bridge circuits (14A to 14D) may be provided and the input voltage monitoring unit (40) may be shared by the plural bridge circuits (14A to 14D). Thereby, it is possible to downsize the detecting device (10) and suppress the manufacturing cost.

In the above detecting device (10), the plurality of the bridge circuits (14A to 14D) may be provided. Further, the resistance of the sensing resistor (31) may vary depending on a target physical quantity of the measurement object and a physical quantity other than the target physical quantity, the bridge circuit (14A to 14D) may include a reference resistor (33) whose resistance varies depending on the physical quantity other than the target physical quantity of the measurement object, and the reference resistor (33) may be shared by the plural bridge circuits (14A to 14D). Thereby, it is possible to downsize the detecting device (10) and suppress the manufacturing cost.

The present invention is not particularly limited to the embodiments described above, and various modifications are possible without departing from the essence and gist of the present invention.

What is claimed is:

1. A detecting device comprising:
a bridge circuit having a plurality of resistors including at least one sensing resistor whose resistance varies according to a physical quantity of a measurement object;
a constant voltage power supply configured to apply a constant voltage to the bridge circuit;
a first amplifier having high-impedance input terminals and configured to receive an input voltage of the bridge circuit from the input terminals, amplify the received input voltage and output the amplified input voltage; and
an input voltage monitoring unit configured to receive the input voltage amplified by the first amplifier and monitor a voltage of the input voltage,
wherein the bridge circuit is connected to the first amplifier via a connector.

2. The detecting device according to claim 1, wherein:
the bridge circuit is provided on a first substrate; and
the first amplifier is provided on a second substrate provided separately from the first substrate.

3. The detecting device according to claim 1, further comprising:
a second amplifier having high-impedance input terminals and configured to receive an output voltage of the bridge circuit from the input terminals, amplify the received output voltage and output the amplified output voltage; and
a physical quantity calculating unit configured to receive the input voltage amplified by the first amplifier and the output voltage amplified by the second amplifier, and calculate the physical quantity based on the input voltage and the output voltage,
wherein the bridge circuit is connected to the second amplifier via the connector.

4. The detecting device according to claim 3, wherein:
the bridge circuit is provided on a first substrate; and
the first amplifier and the second amplifier are provided on a second substrate provided separately from the first substrate.

5. The detecting device according to claim 1, wherein the plurality of resistors in the bridge circuit are arranged at intervals that are equal to or less than a predetermined distance.

6. The detecting device according to claim 1, wherein wiring between the constant voltage power supply and the resistors is arranged so that a resistance between a negative electrode of the constant voltage power supply and each of the resistors connected to the negative electrode is equal to each other.

7. The detecting device according to claim 1, wherein wiring between the constant voltage power supply and the resistors is arranged so that a resistance between a positive electrode of the constant voltage power supply and each of the resistors connected to the positive electrode is equal to each other.

8. The detecting device according to claim 1, wherein wiring between a negative electrode of the constant voltage power supply and the bridge circuit is formed of a solid pattern having a predetermined width or greater.

9. The detecting device according to claim 1, wherein wiring between a positive electrode of the constant voltage power supply and the bridge circuit is formed of a solid pattern having a predetermined width or greater.

10. The detecting device according to claim 1, further comprising:
a first layer provided with wiring between a positive electrode of the constant voltage power supply and the bridge circuit; and
a second layer provided with the bridge circuit,
wherein the first layer and the second layer are stacked together.

11. The detecting device according to claim 1, further comprising:
a second layer provided with the bridge circuit; and
a third layer provided with wiring between a negative electrode of the constant voltage power supply and the bridge circuit,
wherein the second layer and the third layer are stacked together.

12. The detecting device according to claim 1, further comprising:
a first layer provided with wiring between a positive electrode of the constant voltage power supply and the bridge circuit;
a second layer provided with the bridge circuit; and
a third layer provided with wiring between a negative electrode of the constant voltage power supply and the bridge circuit,
wherein the second layer is sandwiched between the first layer and the third layer.

13. The detecting device according to claim 1, wherein:
the bridge circuit comprises a plurality of bridge circuits; and
the constant voltage power supply is shared by the plurality of bridge circuits.

14. The detecting device according to claim 1, wherein:
the bridge circuit comprises a plurality of bridge circuits; and
the input voltage monitoring unit is shared by the plurality of bridge circuits.

15. The detecting device according to claim 1, wherein:
the bridge circuit comprises a plurality of bridge circuits;
the resistance of the sensing resistor varies depending on a target physical quantity of the measurement object and a physical quantity other than the target physical quantity;
the bridge circuit includes a reference resistor whose resistance varies depending on the physical quantity other than the target physical quantity of the measurement object; and
the reference resistor is shared by the plurality of bridge circuits.
